(19) United States
(12) Patent Application Publication
(10) Pub. No.: US 2018/0355466 A1
(43) Pub. Date: Dec. 13, 2018

(54) FINE METAL MASK AND MANUFACTURE METHOD THEREOF

(71) Applicant: Wuhan China Star Optoelectronics Technology Co., Ltd., Wuhan City (CN)

(72) Inventor: Junying Mu, Wuhan City (CN)

(21) Appl. No.: 15/506,244

(22) PCT Filed: Feb. 17, 2017
(86) PCT No.: PCT/CN2017/073882

§ 371 Date: Feb. 24, 2017

(30) Foreign Application Priority Data
Dec. 28, 2016 (CN) 201611233974.X

(51) Int. Cl. C23C 14/04; C23C 14/24

(52) U.S. Cl. CPC C23C 14/042; H01L 27/3211; C23C 14/24

(57) ABSTRACT

The present invention provides a fine metal mask and a manufacture method thereof. The fine metal mask comprises a mask side frame, a first mask of metal material and a second mask of an organic material; the first mask comprising first pixel openings; the second mask comprising one or more second pixel openings corresponding to an area of each first pixel opening, and because the second pixel openings are arranged in the area corresponding to the first pixel openings, in comparison with prior art, the present invention can provide the pixel openings with a smaller size to manufacture the OLED elements with a smaller size to raise the resolution of the OLED display product; meanwhile, the opening wall slope of the second pixel openings can be controlled to be smaller to make the incident angle of the evaporation material at the second pixel opening edge smaller.

### FIELD OF THE INVENTION

The present invention relates to a manufacture field of an Organic Light Emitting Diode, and more particularly to a fine metal mask and a manufacture method thereof.

### BACKGROUND OF THE INVENTION

Organic Light Emitting Diode (OLED) is a flat panel display technology which has great prospects for development. It possesses extremely excellent display performance, and particularly the properties of self-illumination, simple structure, ultra thin, fast response speed, wide view angle, low power consumption and capability of realizing flexible display, and therefore is considered as the “dream display”. Meanwhile, the investment for the production equipments is far smaller than the TFT-LCD. It has been favored by respective big display makers and has become the main selection of the third generation display element of the display technology field. At present, the OLED has reached the point before mass production. With the further research and development, the new technologies constantly appear, and someday, there will be a breakthrough for the development of the OLED display elements.

The OLED comprises an anode, an organic emitting layer and a cathode sequentially formed on a substrate. As manufacturing the OLED display element, the materials of the respective layers in the OLED need to be evaporated on the array substrate by the evaporation process. In the evaporation process, the corresponding Fine Metal Mask (FMM) is necessary. The OLED material is evaporated on the designed positions through the openings on the FFM. Specifically, by heating the OLED material, the OLED material slowly becomes gaseous sublimation, and then passes through the openings of the FFM to be deposited on the substrate surface to form a thin film. The color display OLED display devices in the current commercial production mainly are RGB three-color OLED display devices and white OLED with color filter (CF) display devices. The RGB three-color OLED display device is widely utilized in the mobile display apparatuses at present. The FMM technology is the determinant of the resolution of the display device.

Generally, the mask is composited with a mask frame and a mask sheet fixed on the mask frame by laser welding. The traditional FMM sheet mainly uses the Invar material, and is manufactured by Double-sided lithography and etching. FIG. 1 is a structure diagram of a traditional FMM. As shown in FIG. 1 in prior art, after a strip shaped fine metal mask 200 having a plurality of pixel openings 210 and a metal frame 100 are aligned by the net machine (mask tension) and connected by laser welding, a whole FMM is formed and then applied to the evaporation process. Generally, the resolution of conventional FMMs is difficult to be applied for manufacturing the display devices with a resolution greater than 250 ppi. With the increasing demand for the display resolution (such as over 300 ppi), the FMM manufacture skill of prior art has already been hard to satisfy the demands. Besides, due to the reasons of the manufacture process, the opening wall of the pixel opening 210 on the fine metal mask 200 possesses a certain slope. Then, as being used in the vacuum evaporation process, the incident angle of the OLED material as passing through the pixel opening 210 at the edge of the pixel opening 210 is too big, and then the set coating area is extended beyond to form a shadow area to further reduce the resolution of the display device.

Therefore, there is a need to design a new fine metal mask and a manufacture method thereof to solve the aforesaid issue.

### SUMMARY OF THE INVENTION

An objective of the present invention is to provide a fine metal mask, which can provide the pixel openings with a smaller size and can be used in the vacuum evaporation process for decreasing the coating shaded area and significantly promoting the resolution of the OLED display product.

An objective of the present invention is to provide a fine metal mask, of which the manufacture method is simple, and the size of the pixel openings of the made fine metal mask is small to be used in the vacuum evaporation process for decreasing the coating shaded area and significantly promoting the resolution of the OLED display product.

For realizing the aforesaid objectives, the present invention provides a fine metal mask, comprising a mask side frame, a first mask fixed on the mask side frame and a second mask located between the mask side frame and the first mask;

the first mask comprising a plurality of first pixel openings;

the second mask comprising one or more second pixel openings corresponding to an area of each first pixel opening;

the first mask being a metal mask, and the second mask being an organic material mask.

A material of the second mask is polyimide or polyamide, and a thickness of the second mask is smaller than 50 μm.

A material of the first mask is invar, and a thickness of first mask is smaller than 200 μm.

The present invention further provides a manufacture method of a fine metal mask, comprising steps of:

step 1, providing a first mask, a net machine and a carrier, and the first mask comprising a plurality of first pixel openings; the net machine comprising a plurality of grippers; using the grippers of the net machine to fix the first mask on the carrier to ensure that the first mask is sufficiently extended;

step 2, providing a substrate, and coating on the substrate to form an organic material film, and implementing a first curing to the organic material film;

step 3, aligning the substrate and the first mask to laminate the substrate with the first mask from a side of the organic material film; implementing a second curing to the organic material film to adhere the organic material film with the first mask;

step 4, separating the substrate and the organic material film, and then the organic material film exposing an edge region of the first mask on the first mask for performing laser welding to the first mask in the region;

step 5, providing a mask side frame to be put into the net machine; transferring the carrier above the mask side frame to implement a coarse alignment to the first mask and the mask side frame;

step 6, fixing two ends of the first mask with the grippers of the net machine to separate the carrier and the first mask;

step 7, turning over the first mask with the grippers to make the organic material film attached to the first mask be located at the uppermost, and then implementing a coarse alignment to the first mask and the mask side frame, and then, implementing a precise alignment to the first mask and the mask side frame with the net machine, and fixing the first mask on the mask side frame by the laser welding;

step 8, using a laser apparatus to laser ablate the organic material film to form a plurality of second pixel openings, wherein a precise alignment is implemented to a laser head of the laser apparatus to position a laser beam emitted by the laser head on the organic material film exposed in the first pixel openings of the first mask, and laser ablating one or more second pixel openings on the organic material film in an area corresponding to each first pixel opening to form the second mask.

The carrier provided in step 1 comprises a carrier substrate, two elastic modules respectively installed at two opposite sides of the carrier substrate, two side pressure members respectively arranged on two sides of the two elastic modules, a top fixing plate arranged above the carrier substrate and movably connected with the two side pressure members, a pressure member driving mechanism, driving the side pressure members to move left and right and a fixing plate driving mechanism, driving the top fixing plate to move up and down;

each side pressure member comprises a side pressure plate, two connection plates respectively and vertically connected with two ends of the side pressure plate to appear to be U shape as a whole; a fixing hole extended downward is arranged on an upper surface of each connection plate;

on two sides of the carrier substrate arranged with the elastic modules, two connection grooves which correspond to the two connection plates corresponding to the side pressure members, are respectively arranged at two sides of the corresponding elastic modules;

a fixing rod extended downward is arranged on a lower surface of the top fixing plate corresponding to each fixing hole.

A process of fixing the first mask on the carrier in step 1 specifically comprises:

step 11, the first mask appearing to be a strip as a whole, and comprising a main part in the middle and connection parts located at two sides of the main part, and using the grippers of the net machine to grip the two ends of the first mask, and the first mask being stretched toward the two ends by the grippers of the first mask, and after mechanical alignment, the main part of the first mask being laminated with a lower surface of the carrier substrate, and the two ends of the first mask being lifted up by the grippers to make the connection part of the first mask be bent upward and respectively be laminated on the elastic modules at the two sides of the carrier substrate;

step 12, driving the side pressure members by the pressure member driving mechanism to insert the two connection plates of each side pressure member into the corresponding connection grooves, and each side pressure member applying pressure to the corresponding elastic module to make the fixing hole on each connection plate reach a position below the corresponding fixing rod;

step 13, inserting the fixing rods of the top fixing plate into the corresponding fixing holes by the fixing plate driving mechanism;

step 14, removing the pressure member driving mechanism and the fixing plate driving mechanism, and then each side pressure member receiving an elastic force of outward extrusion under action of the corresponding elastic module, and the fixing hole on each side pressure member being blocked by the corresponding fixing rod to fix the side pressure member, and meanwhile, the connection part of the first mask being clamped between the side pressure plate and the elastic module and fixed by extrusion of the two.

A process of separating the carrier and the first mask in step 6 specifically comprises:

step 61, making all the side pressure members respectively apply pressure to the corresponding elastic modules by the pressure member driving mechanism to make that a hole wall of the fixing hole is not contacted with and separated from the corresponding fixing rod;

step 62, moving the top fixing plate and the fixing rod thereof upward by the fixing plate driving mechanism to separate the top fixing plate and the carrier substrate;

step 63, making the pressure member driving mechanism slowly release the pressure of the corresponding elastic modules to separate the connection part of the first mask and the elastic modules;

step 64, applying a certain tension to the first mask by the grippers gripping the two ends of the first mask to maintain an extended state, and holding the tension with the grippers and moving to two sides until the entire first mask being in a plane, and separating the first mask and the carrier substrate.

A material of the second mask is polyimide or polyamide, and a thickness of the second mask is smaller than 50 μm.

A material of the first mask is invar, and a thickness of first mask is smaller than 200 μm.

In step 2, the organic material film is coated on the substrate by slit coating, spraying or spin coating;

in step 2, the first curing is implemented to the organic material film by heat curing or UV curing;

in step 3, the second curing is implemented to the organic material film by heat curing or UV curing;

in step 4, the substrate and the organic material film are separated by laser lift-off;

in step 3 and step 5, the alignment is implemented by CCD (charge-coupled device) alignment or mechanical alignment;

in step 7, the coarse alignment is implemented by CCD alignment or mechanical alignment, and the precise alignment is implemented by CCD alignment;

in step 8, the alignment is implemented by CCD alignment.

The present invention further provides a manufacture method of a fine metal mask, comprising steps of:

step 1, providing a first mask, a net machine and a carrier, and the first mask comprising a plurality of first pixel openings; the net machine comprising a plurality of grippers; using the grippers of the net machine to fix the first mask on the carrier to ensure that the first mask is sufficiently extended;

step 2, providing a substrate, and coating on the substrate to form an organic material film, and implementing a first curing to the organic material film;

step 3, aligning the substrate and the first mask to laminate the substrate with the first mask from a side of the organic material film; implementing a second curing to the organic material film to adhere the organic material film with the first mask;

step 4, separating the substrate and the organic material film, and then the organic material film exposing an edge region of the first mask on the first mask for performing laser welding to the first mask in the region;

step 5, providing a mask side frame to be put into the net machine; transferring the carrier above the mask side frame to implement a coarse alignment to the first mask and the mask side frame;

step 6, fixing two ends of the first mask with the grippers of the net machine to separate the carrier and the first mask;

step 7, turning over the first mask with the grippers to make the organic material film attached to the first mask be located at the uppermost, and then implementing a coarse alignment to the first mask and the mask side frame, and then, implementing a precise alignment to the first mask and the mask side frame with the net machine, and fixing the first mask on the mask side frame by the laser welding;

step 8, using a laser apparatus to laser ablate the organic material film to form a plurality of second pixel openings, wherein a precise alignment is implemented to a laser head of the laser apparatus and the first mask to position a laser beam emitted by the laser head on the organic material film exposed in the first pixel openings of the first mask, and laser ablating one or more second pixel openings on the organic material film in an area corresponding to each first pixel opening to form the second mask;

wherein the carrier provided in step 1 comprises a carrier substrate, two elastic modules respectively installed at two opposite sides of the carrier substrate, two side pressure members respectively arranged on two sides of the two elastic modules, a top fixing plate arranged above the carrier substrate and movably connected with the two side pressure members, a pressure member driving mechanism, driving the side pressure members to move left and right and a fixing plate driving mechanism, driving the top fixing plate to move up and down;

each side pressure member comprises a side pressure plate, two connection plates respectively and vertically connected with two ends of the side pressure plate to appear to be U shape as a whole; a fixing hole extended downward is arranged on an upper surface of each connection plate;

on two sides of the carrier substrate arranged with the elastic modules, two connection grooves which correspond to the two connection plates corresponding to the side pressure members, are respectively arranged at two sides of the corresponding elastic modules;

a fixing rod extended downward is arranged on a lower surface of the top fixing plate corresponding to each fixing hole;

wherein a material of the second mask is polyimide or polyamide, and a thickness of the second mask is smaller than 50 μm;

wherein a material of the first mask is invar, and a thickness of first mask is smaller than 200 μm.

The benefits of the present invention are: the present invention provides a fine metal mask, comprising a mask side frame, a first mask of metal material and a second mask of an organic material; the first mask comprising a plurality of first pixel openings; the second mask comprising one or more second pixel openings corresponding to an area of each first pixel opening, and because the second pixel openings are correspondingly arranged in the area corresponding to the first pixel openings, in comparison with the FMM of prior art, the present invention can provide the pixel openings with a smaller size to manufacture the OLED elements with a smaller size in the vacuum evaporation process to raise the resolution of the OLED display product; meanwhile, the opening wall slope of the second pixel openings can be controlled to be smaller to make the incident angle of the evaporation material at the second pixel opening edge smaller in the vacuum evaporation process for decreasing the coating shaded area and promoting the resolution of the OLED display product in advance. The manufacture method of the fine metal mask of the present invention is simple. The made fine metal mask comprises the second mask of organic material. The second mask comprises second pixel openings with a smaller size, and the opening wall slope of the second pixel openings can be controlled to be smaller, and the fine metal mask can be applied in the vacuum evaporation process to make the incident angle of the evaporation material at the second pixel opening edge smaller for decreasing the coating shaded area and significantly promoting the resolution of the OLED display product.

In order to better understand the characteristics and technical aspect of the invention, please refer to the following detailed description of the present invention is concerned with the diagrams, however, provide reference to the accompanying drawings and description only and is not intended to be limiting of the invention.

### BRIEF DESCRIPTION OF THE DRAWINGS

The technical solution and the beneficial effects of the present invention are best understood from the following detailed description with reference to the accompanying figures and embodiments.

In drawings,

FIG. 1 is a structure diagram of a traditional fine metal mask (FMM);

FIG. 2 is a structure diagram of a fine metal mask of the present invention;

FIG. 3 is a flowchart of a manufacture method of a fine metal mask of the present invention;

FIG. 4 is a diagram of step 1 of a manufacture method of a fine metal mask of the present invention;

FIG. 5 is a top view diagram of a carrier used in a manufacture method of a fine metal mask of the present invention;

FIG. 6 is a diagram of step 2 of a manufacture method of a fine metal mask of the present invention;

FIG. 7 is a diagram of step 3 of a manufacture method of a fine metal mask of the present invention;

FIG. 8 is a diagram of step 4 of a manufacture method of a fine metal mask of the present invention;

FIG. 9 is a diagram of step 5 of a manufacture method of a fine metal mask of the present invention;

FIG. 10 is a diagram of step 7 of a manufacture method of a fine metal mask of the present invention;

FIG. 11 is a sectional diagram of a first mask and an organic material film at a position corresponding to a first pixel opening before implementing laser ablation in step 8 of a manufacture method of a fine metal mask of the present invention;

FIG. 12 is a sectional diagram of a first mask and a second mask at a position corresponding to a first pixel opening after implementing laser ablation in step 8 of a manufacture method of a fine metal mask of the present invention;

FIG. 13 is a top view diagram of a first mask and an organic material film at a position corresponding to a portion of first pixel openings before implementing laser ablation in step 8 of a manufacture method of a fine metal mask of the present invention;

FIG. 14 is a top view diagram of a first mask and a second mask at a position corresponding to a portion of first pixel openings after implementing laser ablation in step 8 of a manufacture method of a fine metal mask of the present invention.

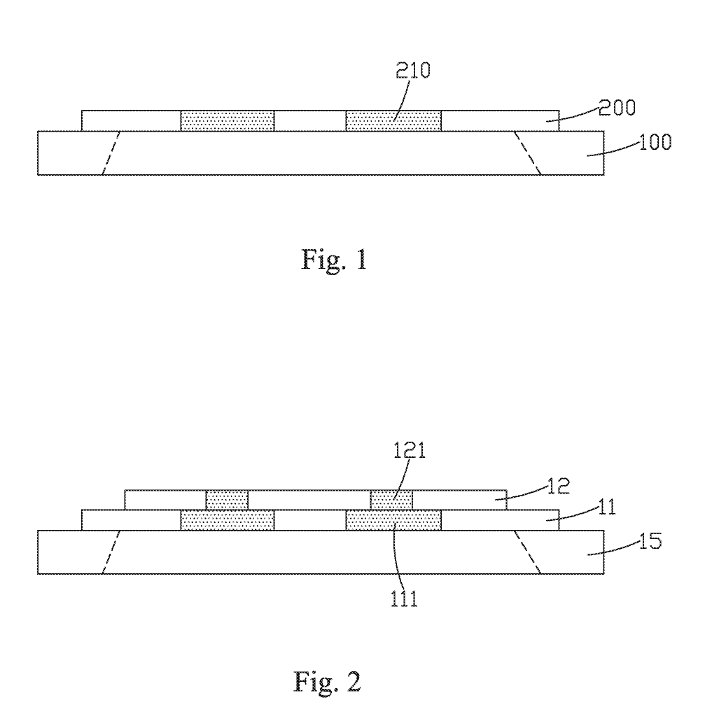

### DETAILED DESCRIPTION OF PREFERRED EMBODIMENTS

For better explaining the technical solution and the effect of the present invention, the present invention will be further described in detail with the accompanying drawings and the specific embodiments.

Please refer to FIG. 2. The present invention provides a fine metal mask, comprising a mask side frame 15, a first mask 11 fixed on the mask side frame 15 and a second mask 12 located on the first mask 11;

the first mask 11 comprising a plurality of first pixel openings 111;

the second mask 12 comprising one or more second pixel openings 121 corresponding to an area of each first pixel opening 111;

the first mask 11 being a metal mask, and the second mask 12 being an organic material mask.

Specifically, a material of the second mask 12 is polyimide or polyamide, and a thickness of the second mask 12 is smaller than 50 μm, and preferably is 20 μm or thinner, and the second pixel openings 121 thereon can be formed by a method of laser ablation.

Specifically, the first mask 11 can use the fine metal mask (FMM sheet) or prior art, and a material thereof can choose invar, and a thickness thereof is smaller than 200 μm, and preferably is 50 μm or thinner.

Specifically, in this embodiment, the second mask 12 comprising two second pixel openings 121 corresponding to each first pixel opening 111.

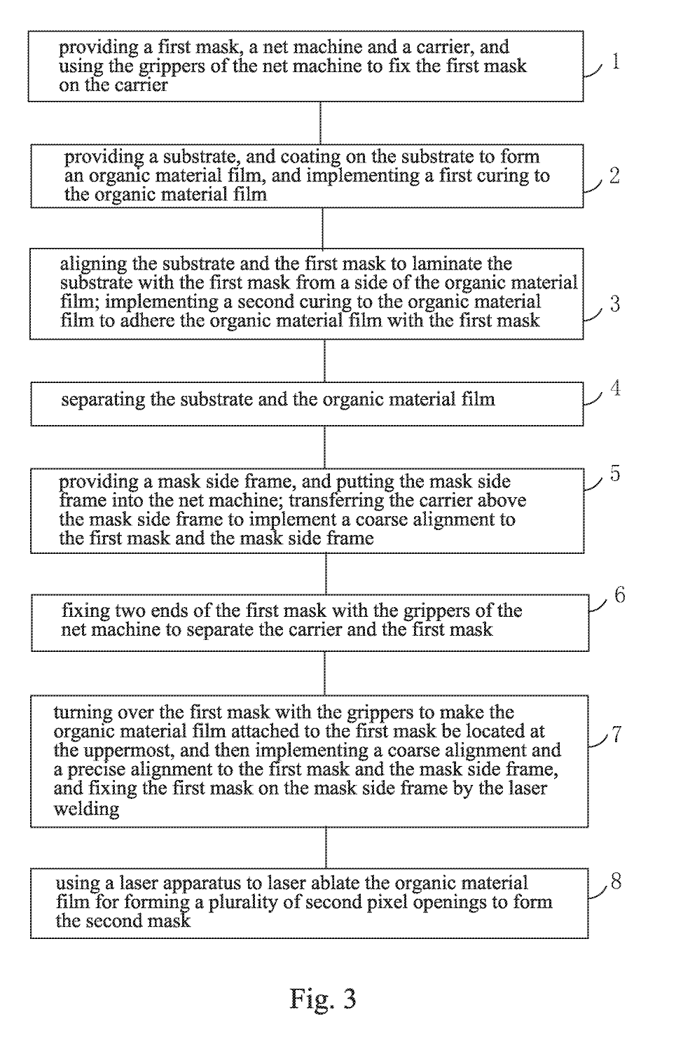

In comparison with the FMM of prior art, the fine metal mask of the present invention further comprises the second mask 12 of organic material, as shown in FIG. 2. A width w2 of the second pixel opening 121 on the second mask 12 is smaller than a width w1 of the first pixel opening 111. Namely, in comparison with the FMM of prior art, the fine metal mask of the present invention can provide the pixel opening with a smaller size to manufacture the OLED elements with a smaller size in the vacuum evaporation process to raise the resolution of the OLED display product; besides, the second pixel opening 121 can be formed by a method of laser ablation, and the opening wall slope thereof can be controlled to be smaller, and the fine metal mask of the present invention can be used in the vacuum evaporation process to make the incident angle Θ2 of the evaporation material at the edge of the second pixel opening 121 smaller than the incident angle Θ1 that only outgoes from the edge of the first pixel opening 111 for decreasing the coating shaded area and significantly promoting the resolution of the OLED display product. Please refer to FIG. 3. The present invention further provides a manufacture method of the aforesaid fine metal mask, comprising steps of:

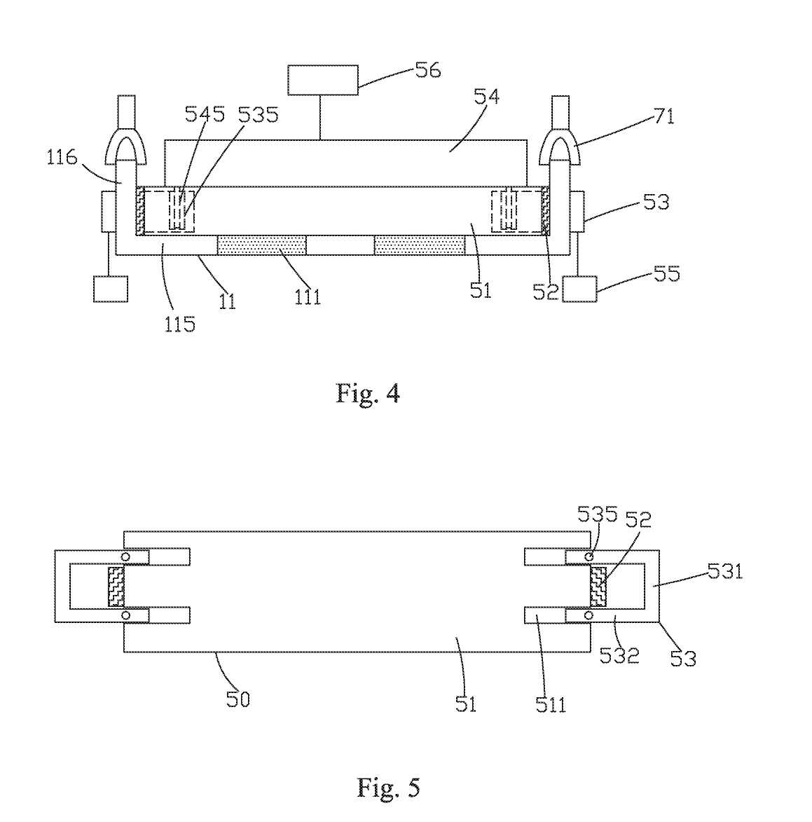

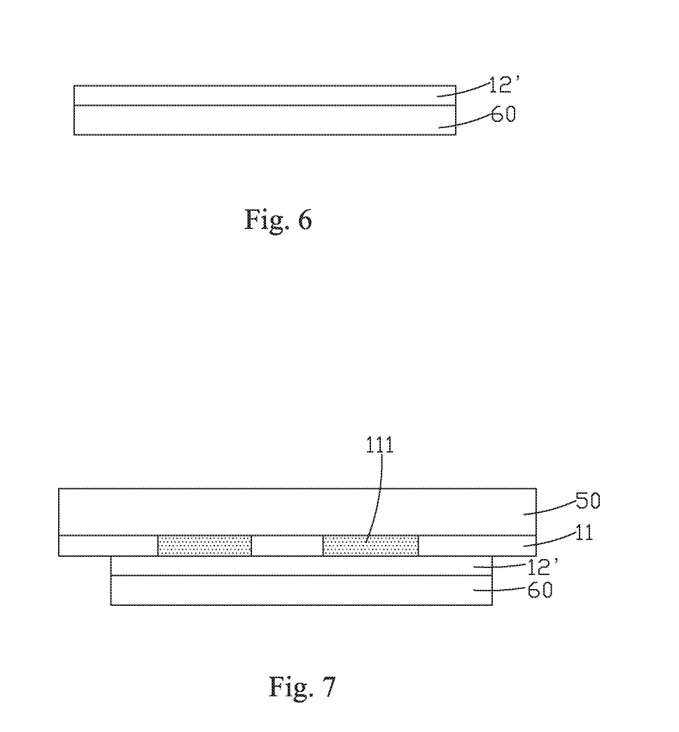

step 1, as shown in FIG. 4, providing a first mask 11, a net machine and a carrier 50, and the first mask 11 comprising a plurality of first pixel openings 111; the net machine comprising a plurality of grippers 71; using the grippers 71 of the net machine to fix the first mask 11 on the carrier 50 to ensure that the first mask 11 is sufficiently extended.

Specifically, a material of the first mask 11 is invar, and a thickness of first mask 11 is smaller than 200 μm.

Specifically, as shown in FIG. 5, the carrier 50 provided in step 1 comprises a carrier substrate 51, two elastic modules 52 respectively installed at two opposite sides of the carrier substrate 51, two side pressure members 53 respectively arranged on two sides of the two elastic modules 52, a top fixing plate 54 arranged above the carrier substrate 51 and movably connected with the two side pressure members 53, a pressure member driving mechanism 55, driving the side pressure members 53 to move left and right and a fixing plate driving mechanism 56, driving the top fixing plate 54 to move up and down;

each side pressure member 53 comprises a side pressure plate 531, two connection plates 532 respectively and vertically connected with two ends of the side pressure plate 531 to appear to be U shape as a whole; a fixing hole 535 extended downward is arranged on an upper surface of each connection plate 532; on two sides of the carrier substrate 51 arranged with the elastic modules 52, two connection grooves 511 which correspond to the two connection plates 532 corresponding to the side pressure members 53, are respectively arranged at two sides of the corresponding elastic modules 52; a fixing rod 545 extended downward is arranged on a lower surface of the top fixing plate 54 corresponding to each fixing hole 535.

A process of fixing the first mask 11 on the carrier 50 in step 1 specifically comprises:

step 11, the first mask 11 appearing to be a strip as a whole, and comprising a main part 115 in the middle and connection parts 116 located at two sides of the main part 115, and using the grippers 71 of the net machine to grip the two ends of the first mask 11, and the first mask 11 being stretched toward the two ends by the grippers 71, and after mechanical alignment, the main part 115 of the first mask 11 being laminated with a lower surface of the carrier substrate 51, and the two ends of the first mask 11 being lifted up by the grippers 71 to make the connection part 116 of the first mask 11 be bent upward and respectively be laminated on the elastic modules 52 at the two sides of the carrier substrate 51.

step 12, driving the side pressure members 53 by the pressure member driving mechanism 55 to insert the two connection plates 532 of each side pressure member 53 into the corresponding connection grooves 511, and each side pressure member 53 applying pressure to the corresponding elastic module 52 to make the fixing hole 535 on each connection plate 532 reach a position below the corresponding fixing rod 545.

step 13, inserting the fixing rods 545 of the top fixing plate 54 into the corresponding fixing holes 535 by the fixing plate driving mechanism 56.

step 14, removing the pressure member driving mechanism 55 and the fixing plate driving mechanism 56, and then each side pressure member 53 receiving an elastic force of outward extrusion under action of the corresponding elastic module 52, and the fixing hole 535 on each side pressure member 53 being blocked by the corresponding fixing rod 545 to fix the side pressure member 53, and meanwhile, the connection part 116 of the first mask 11 being clamped between the side pressure plate 531 and the elastic module 52 and fixed by extrusion of the two.

step 2, as shown in FIG. 2, providing a substrate 60, and using slit coating, spraying or spin coating to coat on the substrate 60 to form an organic material film 12′, and using heat curing or UV curing to implement a first curing to the organic material film 12′.

Specifically, a material of the organic material film 12′ is polyimide or polyamide, and a thickness of the organic material film 12′ is smaller than 20 μm.

step 3, as shown in FIG. 3, using CCD alignment or mechanical alignment to align the substrate 60 and the first mask 11, in which the alignment accuracy is about 200 μm or better, to laminate the substrate 60 with the first mask 11 from a side of the organic material film 12′; using heat curing or UV curing to implement a second curing to the organic material film 12′ to adhere the organic material film 12′ with the first mask 11.

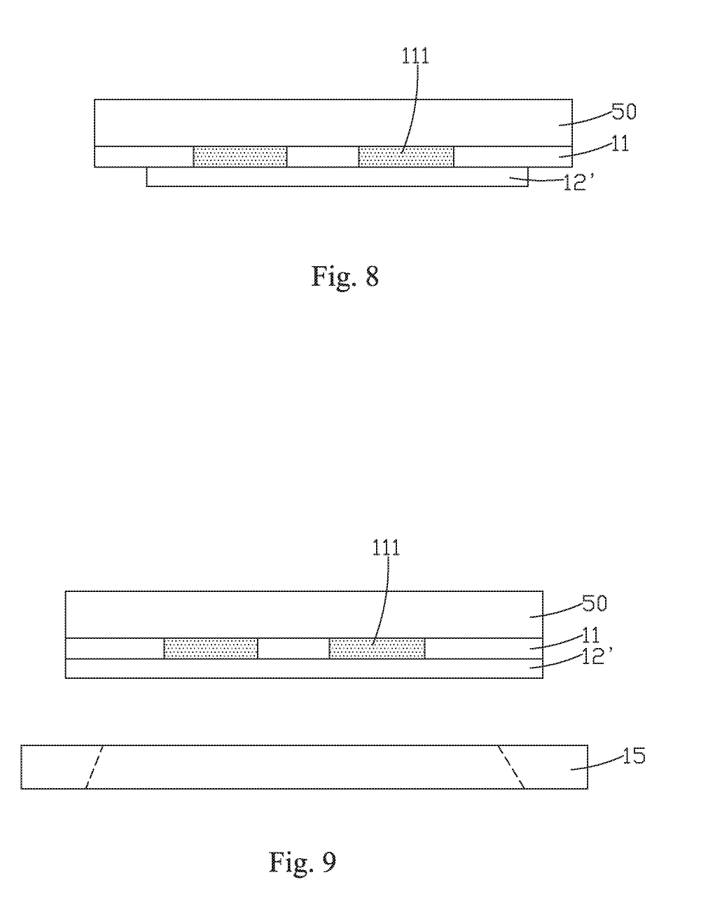

step 4, as shown in FIG. 8, using laser lift-off (LLO) or other skills to separate the substrate 60 and the organic material film 12′, and then the organic material film 12′ exposing an edge region of the first mask 11 on the first mask 11 for performing laser welding to the first mask 11 in the region.

step 5, as shown in FIG. 9, providing a mask side frame 15, and putting the mask side frame 15 into the net machine; transferring the carrier 50 above the mask side frame 15 to implement a coarse alignment to the first mask 11 and the mask side frame 15 by CCD alignment or mechanical alignment, and the alignment accuracy is about 200 μm or better.

step 6, fixing two ends of the first mask 11 with the grippers 71 of the net machine to separate the carrier 50 and the first mask 11.

Specifically, a process of separating the carrier 50 and the first mask 11 in step 6 specifically comprises:

step 61, making all the side pressure members 53 respectively apply pressure to the corresponding elastic modules 52 by the pressure member driving mechanism 55 to make that a hole wall of the fixing hole 535 is not contacted with and separated from the corresponding fixing rod 545.

step 62, moving the top fixing plate 54 and the fixing rod 545 thereof upward by the fixing plate driving mechanism 56 to separate the top fixing plate 54 and the carrier substrate 51.

step 63, making the pressure member driving mechanism 55 slowly release the pressure of the corresponding elastic modules 52 to separate the connection part 116 of the first mask 11 and the elastic modules 52.

step 64, applying a certain tension to the first mask 11 by the grippers 71 gripping the two ends of the first mask 11 to maintain an extended state, and holding the tension with the grippers 71 and moving to two sides until the entire first mask 11 being in an plane, and separating the first mask 11 and the carrier substrate 51.

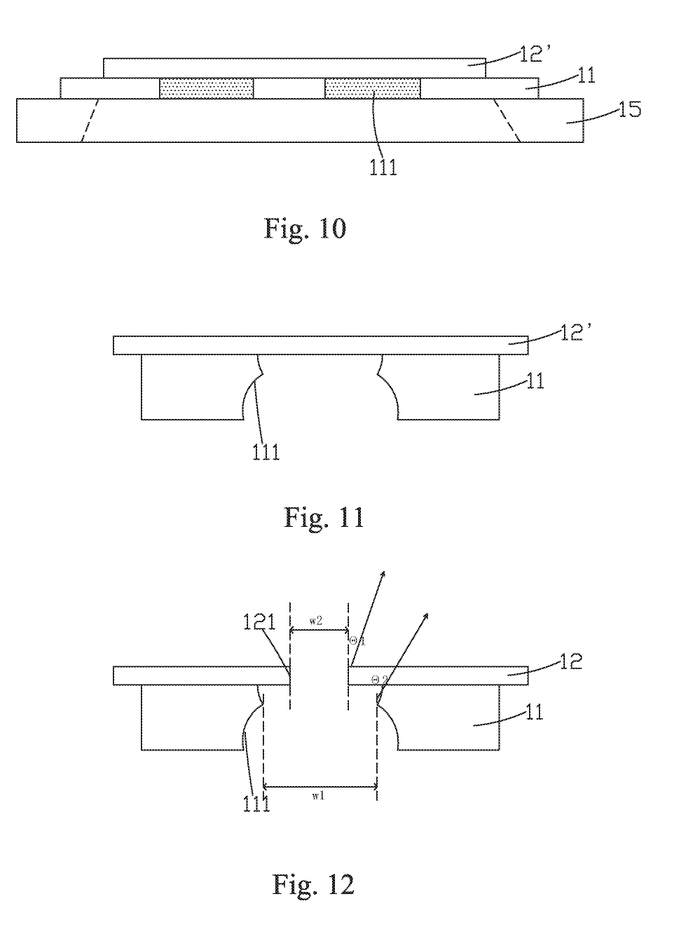

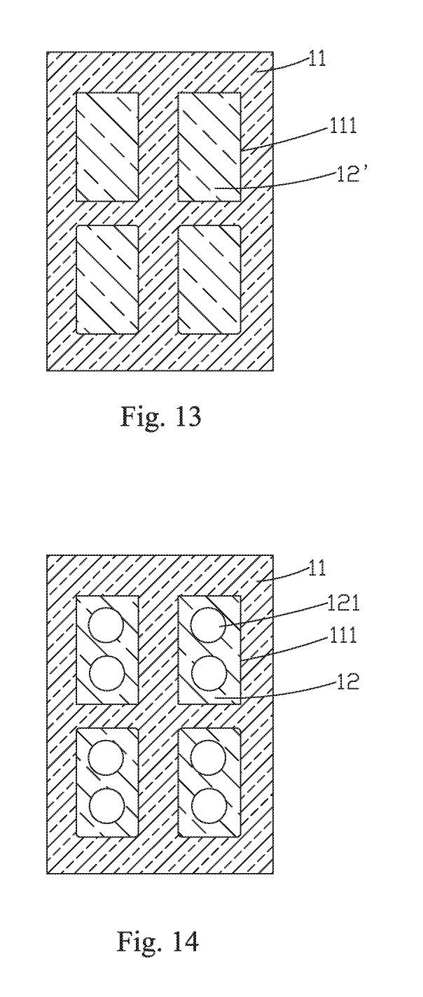

step 7, as shown in FIG. 10, turning over the first mask 11 with the grippers 71 to make the organic material film 12′ attached to the first mask 11 be located at the uppermost, and then using CCD alignment or mechanical alignment to implement a coarse alignment to the first mask 11 and the mask side frame 15, in which the alignment accuracy is 1 mm or better, and then, using CCD alignment to implement a precise alignment to the first mask 11 and the mask side frame 15 with the net machine, in which the alignment accuracy is 1 μm or better, and fixing the first mask 11 on the mask side frame 15 by the laser welding step 8, as shown in FIGS. 11-14, using a laser apparatus to laser ablate the organic material film 12′ to form a plurality of second pixel openings 121, wherein the CCD alignment is used to implement a precise alignment to a laser head of the laser apparatus, in which the alignment accuracy is 2 μm or better, to position a laser beam emitted by the laser head on the organic material film 12′ exposed in the first pixel openings 111 of the first mask 11, and laser ablating one or more second pixel openings 121 on the organic material film 12′ in an area corresponding to each first pixel opening 111 to form the second mask 12 to obtain the fine metal mask shown in FIG. 2.

In conclusion, the fine metal mask provided by the present invention comprises a mask side frame, a first mask of metal material and a second mask of an organic material; the first mask comprising a plurality of first pixel openings; the second mask comprising one or more second pixel openings corresponding to an area of each first pixel opening, and because the second pixel openings are correspondingly arranged in the area corresponding to the first pixel openings, in comparison with the FMM of prior art, the present invention can provide the pixel openings with a smaller size to manufacture the OLED elements with a smaller size in the vacuum evaporation process to raise the resolution of the OLED display product; meanwhile, the opening wall slope of the second pixel openings can be controlled to be smaller to make the incident angle of the evaporation material at the second pixel opening edge smaller in the vacuum evaporation process for decreasing the coating shaded area and promoting the resolution of the OLED display product in advance. The manufacture method of the fine metal mask of the present invention is simple. The made fine metal mask comprises the second mask of organic material. The second mask comprises second pixel openings with a smaller size, and the opening wall slope of the second pixel openings can be controlled to be smaller, and the fine metal mask can be applied in the vacuum evaporation process to make the incident angle of the evaporation material at the second pixel opening edge smaller for decreasing the coating shaded area and significantly promoting the resolution of the OLED display product.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. A fine metal mask, comprising a mask side frame, a first mask fixed on the mask side frame and a second mask located on the first mask;
the first mask comprising a plurality of first pixel openings;
the second mask comprising one or more second pixel openings corresponding to an area of each first pixel opening;
the first mask being a metal mask, and the second mask being an organic material mask.

2. The fine metal mask according to claim 1, wherein a material of the second mask is polyimide or polyamide, and a thickness of the second mask is smaller than 50 μm.

3. The fine metal mask according to claim 1, wherein a material of the first mask is invar, and a thickness of first mask is smaller than 200 μm.

4. A manufacture method of a fine metal mask, comprising steps of:
step 1, providing a first mask, a net machine and a carrier, and the first mask comprising a plurality of first pixel openings; the net machine comprising a plurality of grippers; using the grippers of the net machine to fix the first mask on the carrier to ensure that the first mask is sufficiently extended;
step 2, providing a substrate, and coating on the substrate to form an organic material film, and implementing a first curing to the organic material film;
step 3, aligning the substrate and the first mask to laminate the substrate with the first mask from a side of the organic material film; implementing a second curing to the organic material film to adhere the organic material film with the first mask;
step 4, separating the substrate and the organic material film, and then the organic material film exposing an edge region of the first mask on the first mask for performing laser welding to the first mask in the region;
step 5, providing a mask side frame to be put into the net machine; transferring the carrier above the mask side frame to implement a coarse alignment to the first mask and the mask side frame;
step 6, fixing two ends of the first mask with the grippers of the net machine to separate the carrier and the first mask;
step 7, turning over the first mask with the grippers to make the organic material film attached to the first mask be located at the uppermost, and then implementing a coarse alignment to the first mask and the mask side frame, and then, implementing a precise alignment to the first mask and the mask side frame with the net machine, and fixing the first mask on the mask side frame by the laser welding;
step 8, using a laser apparatus to laser ablate the organic material film to form a plurality of second pixel openings, wherein a precise alignment is implemented to a laser head of the laser apparatus and the first mask to position a laser beam emitted by the laser head on the organic material film exposed in the first pixel openings of the first mask, and laser ablating one or more second pixel openings on the organic material film in an area corresponding to each first pixel opening to form the second mask.

5. The manufacture method of the fine metal mask according to claim 4, wherein the carrier provided in step 1 comprises a carrier substrate, two elastic modules respectively installed at two opposite sides of the carrier substrate, two side pressure members respectively arranged on two sides of the two elastic modules, a top fixing plate arranged above the carrier substrate and movably connected with the two side pressure members, a pressure member driving mechanism, driving the side pressure members to move left and right and a fixing plate driving mechanism, driving the top fixing plate to move up and down;
each side pressure member comprises a side pressure plate, two connection plates respectively and vertically connected with two ends of the side pressure plate to appear to be U shape as a whole; a fixing hole extended downward is arranged on an upper surface of each connection plate;
on two sides of the carrier substrate arranged with the elastic modules, two connection grooves which correspond to the two connection plates corresponding to the side pressure members, are respectively arranged at two sides of the corresponding elastic modules;
a fixing rod extended downward is arranged on a lower surface of the top fixing plate corresponding to each fixing hole.

6. The manufacture method of the fine metal mask according to claim 5, wherein a process of fixing the first mask on the carrier in step 1 specifically comprises:
step 11, the first mask appearing to be a strip as a whole, and comprising a main part in the middle and connection parts located at two sides of the main part, and using the grippers of the net machine to grip the two ends of the first mask, and the first mask being stretched toward the two ends by the grippers of the first mask, and after mechanical alignment, the main part of the first mask being laminated with a lower surface of the carrier substrate, and the two ends of the first mask being lifted up by the grippers to make the connection part of the first mask be bent upward and respectively be laminated on the elastic modules at the two sides of the carrier substrate;
step 12, driving the side pressure members by the pressure member driving mechanism to insert the two connection plates of each side pressure member into the corresponding connection grooves, and each side pressure member applying pressure to the corresponding elastic module to make the fixing hole on each connection plate reach a position below the corresponding fixing rod;
step 13, inserting the fixing rods of the top fixing plate into the corresponding fixing holes by the fixing plate driving mechanism;
step 14, removing the pressure member driving mechanism and the fixing plate driving mechanism, and then each side pressure member receiving an elastic force of outward extrusion under action of the corresponding elastic module, and the fixing hole on each side pressure member being blocked by the corresponding fixing rod to fix the side pressure member, and meanwhile, the connection part of the first mask being clamped between the side pressure plate and the elastic module and fixed by extrusion of the two.

7. The manufacture method of the fine metal mask according to claim 5, wherein a process of separating the carrier and the first mask in step 6 specifically comprises:
step 61, making all the side pressure members respectively apply pressure to the corresponding elastic modules by the pressure member driving mechanism to make that a hole wall of the fixing hole is not contacted with and separated from the corresponding fixing rod;
step 62, moving the top fixing plate and the fixing rod thereof upward by the fixing plate driving mechanism to separate the top fixing plate and the carrier substrate;
step 63, making the pressure member driving mechanism slowly release the pressure of the corresponding elastic modules to separate the connection part of the first mask and the elastic modules;
step 64, applying a certain tension to the first mask by the grippers gripping the two ends of the first mask to maintain an extended state, and holding the tension with the grippers and moving to two sides until the entire first mask being in a plane, and separating the first mask and the carrier substrate.

8. The manufacture method of the fine metal mask according to claim 4, wherein a material of the second mask is polyimide or polyamide, and a thickness of the second mask is smaller than 50 μm.

9. The manufacture method of the fine metal mask according to claim 4, wherein a material of the first mask is invar, and a thickness of first mask is smaller than 200 μm.

10. The manufacture method of the fine metal mask according to claim 4, wherein in step 2, the organic material film is coated on the substrate by slit coating, spraying or spin coating;
in step 2, the first curing is implemented to the organic material film by heat curing or UV curing;
in step 3, the second curing is implemented to the organic material film by heat curing or UV curing;
in step 4, the substrate and the organic material film are separated by laser lift-off;
in step 3 and step 5, the alignment is implemented by CCD (charge-coupled device) alignment or mechanical alignment;
in step 7, the coarse alignment is implemented by CCD alignment or mechanical alignment, and the precise alignment is implemented by CCD alignment;
in step 8, the alignment is implemented by CCD alignment.

11. A manufacture method of a fine metal mask, comprising steps of:
step 1, providing a first mask, a net machine and a carrier, and the first mask comprising a plurality of first pixel openings; the net machine comprising a plurality of grippers; using the grippers of the net machine to fix the first mask on the carrier to ensure that the first mask is sufficiently extended;
step 2, providing a substrate, and coating on the substrate to form an organic material film, and implementing a first curing to the organic material film;
step 3, aligning the substrate and the first mask to laminate the substrate with the first mask from a side of the organic material film; implementing a second curing to the organic material film to adhere the organic material film with the first mask;
step 4, separating the substrate and the organic material film, and then the organic material film exposing an edge region of the first mask on the first mask for performing laser welding to the first mask in the region;
step 5, providing a mask side frame to be put into the net machine; transferring the carrier above the mask side frame to implement a coarse alignment to the first mask and the mask side frame;
step 6, fixing two ends of the first mask with the grippers of the net machine to separate the carrier and the first mask;
step 7, turning over the first mask with the grippers to make the organic material film attached to the first mask be located at the uppermost, and then implementing a coarse alignment to the first mask and the mask side frame, and then, implementing a precise alignment to the first mask and the mask side frame with the net machine, and fixing the first mask on the mask side frame by the laser welding;
step 8, using a laser apparatus to laser ablate the organic material film to form a plurality of second pixel openings, wherein a precise alignment is implemented to a laser head of the laser apparatus and the first mask to position a laser beam emitted by the laser head on the organic material film exposed in the first pixel openings of the first mask, and laser ablating one or more second pixel openings on the organic material film in an area corresponding to each first pixel opening to form the second mask;
wherein the carrier provided in step 1 comprises a carrier substrate, two elastic modules respectively installed at two opposite sides of the carrier substrate, two side pressure members respectively arranged on two sides of the two elastic modules, a top fixing plate arranged above the carrier substrate and movably connected with the two side pressure members, a pressure member driving mechanism, driving the side pressure members to move left and right and a fixing plate driving mechanism, driving the top fixing plate to move up and down;
each side pressure member comprises a side pressure plate, two connection plates respectively and vertically connected with two ends of the side pressure plate to appear to be U shape as a whole; a fixing hole extended downward is arranged on an upper surface of each connection plate;
on two sides of the carrier substrate arranged with the elastic modules, two connection grooves which correspond to the two connection plates corresponding to the side pressure members, are respectively arranged at two sides of the corresponding elastic modules;
a fixing rod extended downward is arranged on a lower surface of the top fixing plate corresponding to each fixing hole;
wherein a material of the second mask is polyimide or polyamide, and a thickness of the second mask is smaller than 50 μm;
wherein a material of the first mask is invar, and a thickness of first mask is smaller than 200 μm.

12. The manufacture method of the fine metal mask according to claim 11, wherein a process of fixing the first mask on the carrier in step 1 specifically comprises:
step 11, the first mask appearing to be a strip as a whole, and comprising a main part in the middle and connection parts located at two sides of the main part, and using the grippers of the net machine to grip the two ends of the first mask, and the first mask being stretched toward the two ends by the grippers of the first mask, and after mechanical alignment, the main part of the first mask being laminated with a lower surface of the carrier substrate, and the two ends of the first mask being lifted up by the grippers to make the connection part of the first mask be bent upward and respectively be laminated on the elastic modules at the two sides of the carrier substrate;
step 12, driving the side pressure members by the pressure member driving mechanism to insert the two connection plates of each side pressure member into the corresponding connection grooves, and each side pressure member applying pressure to the corresponding elastic module to make the fixing hole on each connection plate reach a position below the corresponding fixing rod;
step 13, inserting the fixing rods of the top fixing plate into the corresponding fixing holes by the fixing plate driving mechanism;
step 14, removing the pressure member driving mechanism and the fixing plate driving mechanism, and then each side pressure member receiving an elastic force of outward extrusion under action of the corresponding elastic module, and the fixing hole on each side pressure member being blocked by the corresponding fixing rod to fix the side pressure member, and meanwhile, the connection part of the first mask being clamped between the side pressure plate and the elastic module and fixed by extrusion of the two.

13. The manufacture method of the fine metal mask according to claim 11, wherein a process of separating the carrier and the first mask in step 6 specifically comprises:
step 61, making all the side pressure members respectively apply pressure to the corresponding elastic modules by the pressure member driving mechanism to make that a hole wall of the fixing hole is not contacted with and separated from the corresponding fixing rod;
step 62, moving the top fixing plate and the fixing rod thereof upward by the fixing plate driving mechanism to separate the top fixing plate and the carrier substrate;
step 63, making the pressure member driving mechanism slowly release the pressure of the corresponding elastic modules to separate the connection part of the first mask and the elastic modules;
step 64, applying a certain tension to the first mask by the grippers gripping the two ends of the first mask to maintain an extended state, and holding the tension with the grippers and moving to two sides until the entire first mask being in a plane, and separating the first mask and the carrier substrate.

14. The manufacture method of the fine metal mask according to claim 11, wherein in step 2, the organic material film is coated on the substrate by slit coating, spraying or spin coating;
in step 2, the first curing is implemented to the organic material film by heat curing or UV curing;
in step 3, the second curing is implemented to the organic material film by heat curing or UV curing;
in step 4, the substrate and the organic material film are separated by laser lift-off;
in step 3 and step 5, the alignment is implemented by CCD (charge-coupled device) alignment or mechanical alignment;
in step 7, the coarse alignment is implemented by CCD alignment or mechanical alignment, and the precise alignment is implemented by CCD alignment;
in step 8, the alignment is implemented by CCD alignment.
